(19) United States
(12) Patent Application Publication
(10) Pub. No.: US 2025/0386423 A1
(43) Pub. Date: Dec. 18, 2025

(54) PRINTED CIRCUIT BOARD

(71) Applicant: SAMSUNG ELECTRO-MECHANICS CO., LTD., Suwon-si (KR)

(72) Inventors: Jin Uk LEE, Suwon-si (KR); Tae Kyung LEE, Suwon-si (KR); Chi Hyeon JEONG, Suwon-si (KR); Young Hun YOU, Suwon-si (KR)

(73) Assignee: SAMSUNG ELECTRO-MECHANICS CO., LTD., Suwon-si (KR)

(21) Appl. No.: 19/053,914

(22) Filed: Feb. 14, 2025

(30) Foreign Application Priority Data
Jun. 18, 2024 (KR) 10-2024-0078728

(51) Int. Cl. H05K 1/02; H05K 1/11

(52) U.S. Cl. CPC H05K 1/0228; H05K 1/113; H05K 2201/09227; H05K 2201/096

(57) ABSTRACT

The present disclosure relates to a printed circuit board, the printed circuit including: a first insulating layer; a plurality of first wiring patterns disposed to be spaced apart from each other on the first insulating layer; a first insulating film disposed on the first insulating layer, and covering each of the plurality of first wiring patterns along a surface of each of the plurality of first wiring patterns; a first metal layer covering the first insulating film along a surface of the first insulating film; and a second insulating layer covering the first metal layer, and disposed in at least a portion of spaces between the plurality of first wiring patterns that are spaced apart from each other.

### CROSS-REFERENCE TO RELATED APPLICATIONS

This application claims benefit of priority to Korean Patent Application No. 10-2024-0078728 filed on Jun. 18, 2024, in the Korean Intellectual Property Office, the disclosure of which is incorporated herein by reference in its entirety.

### BACKGROUND

### 1. Field

The present disclosure relates to a printed circuit board.

### 2. Description of Related Art

Demand for a multi-chip package with multiple chips mounted on a substrate is increasing. In addition, as the number of input/output ports on chips increases, high wiring density is also required on the substrate. Meanwhile, as a distance between patterns gets closer when implementing a high-density wiring, signal interference increases.

### SUMMARY

An aspect of the present disclosure is to provide a printed circuit board that can reduce signal interference while maintaining a close distance between a plurality of wiring patterns.

An aspect of the present disclosure is to form an insulating film conformally covering a plurality of wiring patterns on a first insulating layer, form a metal layer conformally covering the insulating film on the insulating film, and to form a second insulating layer covering the metal layer on the metal layer, thereby surrounding at least three surfaces of the plurality of wiring patterns with metal. According to an aspect of the present disclosure, a

printed circuit board, may include: a first insulating layer; a plurality of first wiring patterns disposed to be spaced apart from each other on the first insulating layer; a first insulating film disposed on the first insulating layer, and covering each of the plurality of first wiring patterns along a surface of each of the plurality of first wiring patterns; a first metal layer covering the first insulating film along a surface of the first insulating film; and a second insulating layer covering the first metal layer, and disposed in at least a portion of spaces between the plurality of first wiring patterns that are spaced apart from each other.

According to an aspect of the present disclosure, a printed circuit board, may include an insulating layer; a plurality of wiring patterns disposed to be spaced apart from each other on the insulating layer; an insulating film disposed on the insulating layer, and covering each of the plurality of wiring patterns conforming to the shape of each of the plurality of wiring patterns; and a first metal layer covering the insulating film. The insulating layer and the insulating film may include the same type of insulating material.

According to an aspect of the present disclosure, a printed circuit board, may include an insulating layer; a plurality of wiring patterns disposed to be spaced apart from each other on the insulating layer; an insulating film disposed on the insulating layer, and covering each of the plurality of wiring patterns along a surface of each of the plurality of wiring patterns; a first metal layer covering the insulating film along a surface of the insulating film; and a second metal layer disposed on an opposite side of a side on which the plurality of wiring patterns of the insulating layer are disposed. Each of the plurality of wiring patterns may have at least four surfaces substantially surrounded by the first and second metal layers. A portion of the insulating film disposed between two of the plurality of wiring patterns may be in contact with the insulating layer and the first metal layer.

### BRIEF DESCRIPTION OF DRAWINGS

The above and other aspects, features, and advantages of the present disclosure will be more clearly understood the following detailed description, taken in from conjunction with the accompanying drawings, in which:

FIG. 1 is a block diagram schematically illustrating an example embodiment of an electronic device system;

FIG. 2 is a perspective diagram schematically illustrating an example embodiment of an electronic device;

FIG. 3 is a cross-sectional diagram schematically illustrating an example embodiment of a printed circuit board;

FIG. 4 is a schematic plan view illustrating the A-A′ cross-section of the printed circuit board of FIG. 3;

FIG. 5 is a schematic cross-sectional view illustrating another example embodiment of a printed circuit board;

FIG. 6 is a schematic cross-sectional view illustrating another example embodiment of a printed circuit board;

FIG. 7 is a schematic cross-sectional view illustrating another example embodiment of a printed circuit board;

FIG. 8 is a schematic cross-sectional view illustrating another example embodiment of a printed circuit board;

FIG. 9 is a schematic cross-sectional view illustrating another example embodiment of a printed circuit board;

FIG. 10 is a schematic cross-sectional view illustrating another example of a printed circuit board;

FIG. 11 is a schematic cross-sectional view illustrating another example embodiment of a printed circuit board;

FIG. 12 is a schematic cross-sectional view illustrating another example embodiment of a printed circuit board;

FIG. 13 is a schematic cross-sectional view illustrating another example embodiment of a printed circuit board; and

FIG. 14 is a schematic cross-sectional view illustrating another example embodiment of a printed circuit board.

### DETAILED DESCRIPTION

Hereinafter, embodiments of the present disclosure will be described as follows with reference to the attached drawings.

### Electronic Device

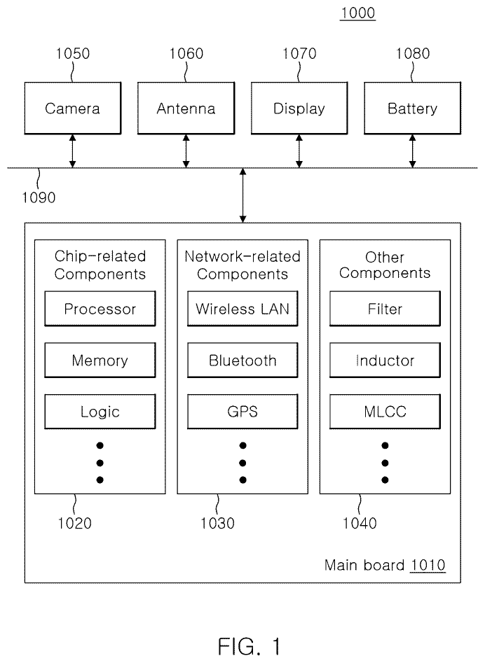

FIG. 1 is a block diagram illustrating an example embodiment of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

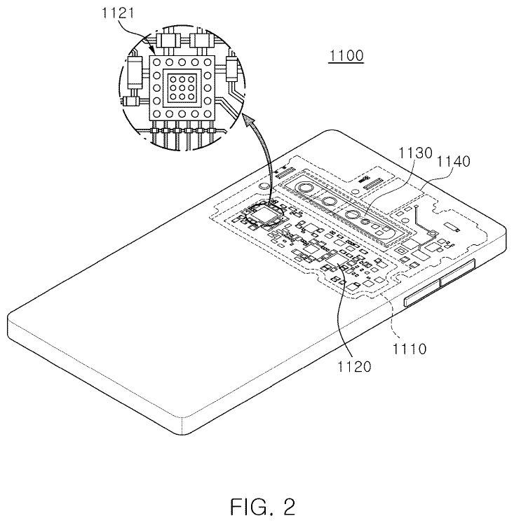

FIG. 2 is a perspective diagram illustrating an example embodiment of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Circuit Board

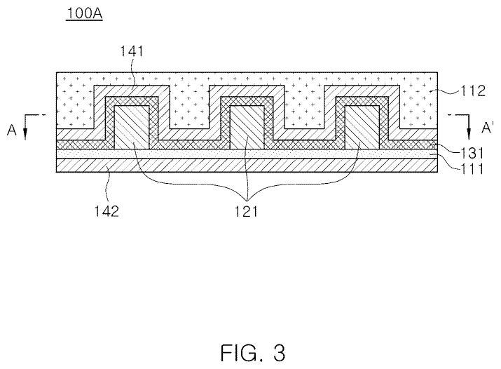

FIG. 3 is a cross-sectional view schematically illustrating an example embodiment of a printed circuit board.

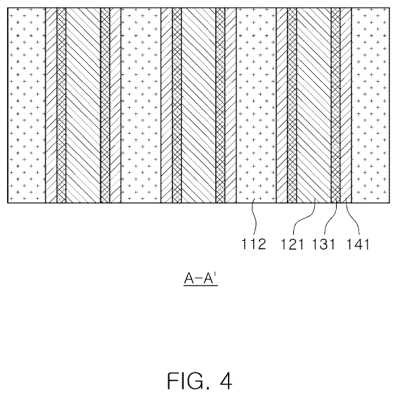

FIG. 4 is a plan view schematically illustrating the A-A′ cross-section of the printed circuit board of FIG. 3.

Referring to the drawings, a printed circuit board 100A according to an example may include a first insulating layer 111, a plurality of wiring patterns 121 disposed to be spaced apart from each other on the first insulating layer 111, an insulating film 131 disposed on the first insulating layer 111 and covering each of the plurality of wiring patterns 121 along a surface of each of the plurality of wiring patterns 121, a first metal layer 141 covering the insulating film 131 along a surface of the insulating film 131, and a second insulating layer 112 covering the first metal layer 141 and filling at least a portion spaces between the plurality of first wiring patterns 121 that are spaced apart from each other. Meanwhile, “covering . . . along a surface” and/or “covering . . . conforming to a shape” may refer to being substantially conformally formed on an outer surface of a target configuration. For example, the insulating film 131 may continuously cover the first insulating layer 111 and the plurality of wiring patterns 121 with a substantially constant thickness, and the first metal layer 141 may continuously cover the insulating film 131 with a substantially constant thickness.

Meanwhile, as described above, when implementing high-density wiring, signal interference increases as a distance between patterns gets closer. Therefore, it may be considered to dispose a ground layer above and/or below a signal line, to attenuate the influence or neighboring wiring. However, in the case of the high-density wiring, it may be difficult to sufficiently reduce signal interference by simply disposing a ground layer thereabove and/or therebelow. Therefore, it may be considered to reduce signal interference by inserting a ground line between signal lines. However, in this case, physical wiring density may increase, and a cross-sectional area of signal wiring may decrease.

On the other hand, a printed circuit board 100A according to an example may form an insulating film 131 with a predetermined thickness along surfaces of a plurality of wiring patterns 121 as described above, a first metal layer 141 with a predetermined thickness along a surface thereof on the insulating 131, film thereby substantially surrounding at least three surfaces of each of the plurality of wiring patterns 121 with metal. Each of the plurality of wiring patterns 121 may include a signal pattern, and the first metal layer 141 may include a ground pattern. Therefore, signal interference may be reduced while maintaining the distance between the plurality of wiring patterns 121 to be close to each other. Therefore, signal characteristics may be improved, a thickness of a product may be reduced, and the wiring density may be increased. In addition, by forming a second insulating layer 112 covering the first metal layer 141 on the first metal layer 141, a planarized insulating surface may be provided, and as a result thereof, a plurality of wiring patterns, or the like, may be easily formed on the second insulating layer 112 as described below.

Meanwhile, the printed circuit board 100A according to an example may further include a second metal layer 142 disposed on an opposite side of the side on which the plurality of wiring patterns 121 of the first insulating layer 111 are disposed. The second metal layer 142 may include a ground pattern. In this case, each of the plurality of wiring patterns 121 may have at least four surfaces substantially surrounded by the first and second metal layers 141 and 142 with metal. Therefore, signal interference may be reduced more effectively. Therefore, signal characteristics may be improved more effectively, and wiring density may be increased more effectively.

Meanwhile, each of the first insulating layer 111, the second insulating layer 112, and the insulating film 131 may include an inorganic insulating material and/or an organic insulating material. For example, the first and second insulating layers 111 and 112 may include the same type of insulating material, and the insulating material 131 may include a different type of insulating material. For example, each of the first and second insulating layers 111 and 112 may include an organic insulating material, and the insulating film 131 may include an inorganic insulating material. However, an embodiment thereof is not limited thereto, and for example, the first insulating layer 111 and the insulating film 131 may include the same type of insulating material, and the second insulating layer 112 may include a different type of insulating material. For example, each of the first insulating layer 111 and the insulating film 131 may include an inorganic insulating material, and the second insulating layer 112 may include an organic insulating material. Meanwhile, when the first insulating layer 111 and the insulating film 131 include an inorganic insulating material, the insulating properties around at least four surfaces of each of the plurality of wiring patterns 121 may be improved. In addition, when the second insulating layer 112 includes an organic insulating material, it may be advantageous for planarization.

Meanwhile, the plurality of wiring patterns 121 may be microcircuits in which lines (L)/spaces(S) are 10 μm/less than 10 μm, for example, 5 μm/within 5 μm, or 2 μm/within 2 μm. In addition, a thickness of each of the first metal layer 141 and the insulating film 131 may be thinner than a thickness of each of the plurality of wiring patterns 121. For example, each of the first metal layer 141 and the insulating film 131 may be a thin film having a thickness of less than 2 μm or less than 1 μm, but an embodiment thereof is not limited thereto.

Meanwhile, each of the plurality of wiring patterns 121 may have a rectangular shape in which a width of a surface thereof, adjacent to the first insulating layer 111 is substantially the same as a width of a surface on the opposite side, in cross-section, but an embodiment thereof is not limited thereto.

Hereinafter, components of the printed circuit board 100A according to an example will be described in more detail with reference to the drawings.

Each of the first and second insulating layers 111 and 112 and the insulating film 131 may include an insulating material. The insulating material may include an organic insulating material and/or an inorganic insulating material. The organic insulating material may include a thermosetting resin such as an epoxy resin, a thermoplastic resin such as polyimide, or a material including an inorganic filler, an organic filler, and/or glass fiber (glass cloth, glass fabric), or the like, together with these resins. For example, the organic insulating material may be a non-photosensitive insulating material such as Copper Clad Laminate (CCL), Ajinomoto Build-up Film (ABF), Prepreg (PPG), or the like, but the present disclosure is not limited thereto, and other polymer materials may also be used. In addition, the organic insulating material may be a photosensitive insulating material such as a Photo Imageable Dielectric (PID). The inorganic insulating material may include an inorganic oxide film that can be formed by Atomic Layer Deposition (ALD), Molecular Vapor Deposition (MVD), or the like, and may include at least one of Al₂O₃, TiO₂, Zno, ZnO₂, ZrO₂, SnO, SnO₂, HfO₂, and SiO₂, preferably Al₂O₃, but an embodiment thereof is not limited thereto, and may include other inorganic materials in addition thereto.

Each of the plurality of wiring patterns 121 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu). Each of the plurality of wiring patterns 121 may include a signal pattern. Each of the patterns may have a line shape. Each of the plurality of wiring patterns 121 may include an electroless plating layer (e.g., chemical copper) and an electrolytic plating layer (e.g., electrolytic copper). A sputter layer may be formed instead of an electroless plating layer (or chemical copper), or both thereof may be included, if necessary.

Each of the first and second metal layers 141 and 142 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but an embodiment thereof is not limited thereto. Each of the first and second metal layers 141 and 142 may include a ground pattern. Each of these patterns may have a plane shape. The first metal layer 141 may be formed by a deposition method such as sputtering. For example, the first metal layer 141 may include a sputtering layer. However, the present disclosure is not limited thereto, and may include an electroless plating layer (e.g., chemical copper) and/or an electrolytic plating layer (e.g., electrolytic copper). The second metal layer 142 may include an electroless plating layer (e.g., chemical copper) and/or an electrolytic plating layer (e.g., electrolytic copper). A sputter layer may be formed instead of an electroless plating layer (or chemical copper), or both thereof may be included, if necessary.

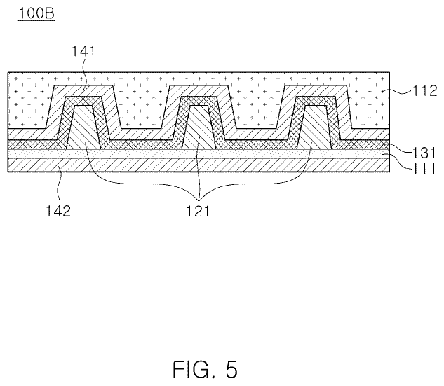

FIG. 5 is a cross-sectional view schematically illustrating another example embodiment of a printed circuit board.

Referring to FIG. 5, in the printed circuit board 100A according to the example described above, in a printed circuit board 100B according to another example, each of the plurality of wiring patterns 121 may have a substantially trapezoidal shape in which a width of a surface thereof, adjacent to the first insulating layer 111 is wider than a width of a surface on the opposite side in cross-section. In this case, it may be easier for the insulating film 131 and the first metal layer 141 to surround each of the plurality of wiring patterns 121. In addition, it may be easier to form the insulating film 131 and the first metal layer 141 through a deposition process. The trapezoidal shape may be formed by forming a pattern through a plating process and then narrowing an upper portion of the pattern through an etching. Alternatively, the appropriate amount of photoresist shape may be formed into a reverse taper shape and then a trapezoidal shape may be implemented through plating or dry deposition. In addition, other methods may be used. Other contents thereof may be substantially the same as described above, and redundant descriptions are omitted.

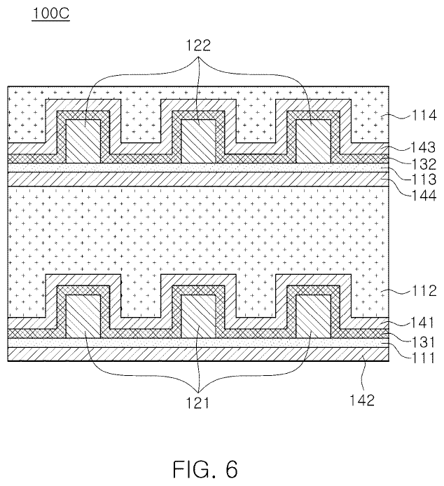

FIG. 6 is a cross-sectional view schematically illustrating another example embodiment of a printed circuit board.

Referring to FIG. 6, in the printed circuit board 100A according to the example described above, a printed circuit board 100C according to another example may further include a third insulating layer 113 disposed on the second insulating layer 112, a plurality of second wiring patterns 122 disposed to be spaced apart from each other on the third insulating layer 113, a second insulating film 132 disposed on the third insulating layer 113 and covering each of the plurality of second wiring patterns 122 along a surface of each of the plurality of second wiring patterns 122, a third metal layer 143 covering the second insulating film 132 along a surface of the second insulating film 132, a fourth insulating layer 114 covering the third metal layer 143 and filling at least a portion of spaces between the plurality of second wiring patterns 122 that are spaced apart from each other, and a fourth metal layer 144 disposed between the second and third insulating layers 112 and 113. For example, the printed circuit board 100C may have a multilayer printed circuit board structure. The contents of each of the first and second insulating layers 111 and 112 and the first insulating film 131, the plurality of first wiring patterns 121, and the first and second metal layers 141 and 142 described above, may be substantially equally applied to each of the third and fourth insulating layers 113 and 114, the second insulating film 132, the plurality of second wiring patterns 122, and the third and fourth metal layers 143 and 144. If necessary, the structural features of the printed circuit board 100B according to another example may be applied to a printed circuit board 100C according to another example. Other contents thereof may be substantially the same as described above, and redundant descriptions are omitted.

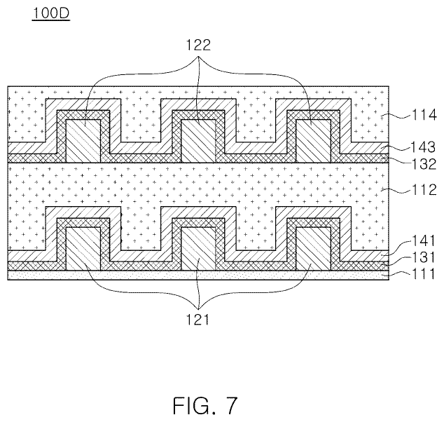

FIG. 7 is a cross-sectional diagram schematically illustrating another example embodiment of a printed circuit board.

Referring to FIG. 7, in the printed circuit board 100C according to the example described above, a printed circuit board 100D according to another example may have a thinner thickness than the second insulating layer 112. For example, an insulating distance between the plurality of first and second wiring patterns 121 and 122 may be smaller. In this case, a fourth metal layer 144 may be omitted. For example, each of a plurality of second wiring patterns 122 and a second insulating film 132 may be directly disposed on the second insulating layer 112. For example, the role of the fourth metal layer 144 may be replaced by using the first metal layer 141. In addition, a second metal layer 142 may be omitted. For example, when at least three surfaces are surrounded with metal, sufficiently blocking signal interference, the second metal layer 142 may also be omitted. In this case, a thin multilayer printed circuit board structure may be implemented. However, the present disclosure is not limited thereto, and the fourth metal layer 144 may be omitted, but the second metal layer 142 may not be omitted. If necessary, the structural features of the printed circuit board 100B according to another example may be applied to a printed circuit board 100D according to another example. Other contents thereof may be substantially the same as described above, and redundant descriptions are omitted.

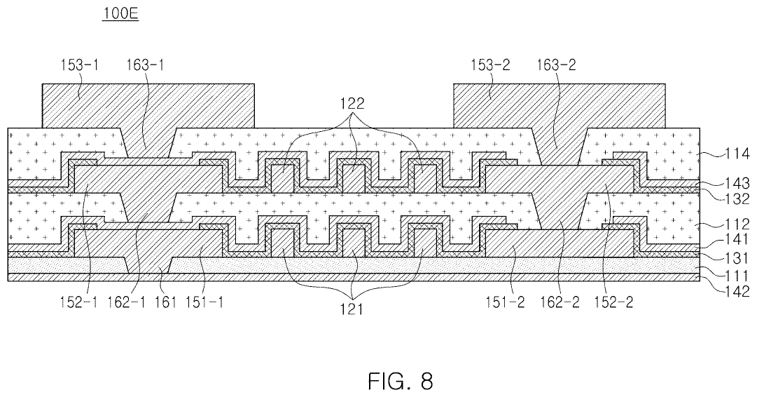

FIG. 8 is a cross-sectional view schematically illustrating another example embodiment of a printed circuit board.

Referring to FIG. 8, in the printed circuit board 100D according to another example described above, a printed circuit board 100E according to another example may further include 1-1 and 1-2 pad patterns 151-1 and 151-2 respectively disposed on the first insulating layer 111, 2-1 and 2-2 pad patterns 152-1 and 152-2 respectively disposed on the second insulating layer 112, 3-1 and 3-2 pad patterns 153-1 and 153-2 respectively disposed on the fourth insulating layer 114, a first via pattern 161 penetrating through the first insulating layer 111 and connecting the 1-1 pad pattern 151-1 and the second metal layer 142 to each other, a 2-1 via pattern 162-1 penetrating through the second insulating layer 112 and connecting the 1-1 and 2-1 pad patterns 151-1 and 151-2 to each other, a 2-2 via pattern 162-2 penetrating through the second insulating layer 112 and connecting the 1-2 and 2-2 pad patterns 151-2 and 152-2 to each other, a 3-1 via pattern 163-1 penetrating through the fourth insulating layer 114 and connecting the 2-1 and 3-1 pad patterns 152-1 and 153-1 to each other, and a 3-2 via pattern 163-2 penetrating through the fourth insulating layer 114 and connecting the 2-2 and 3-2 pad patterns 152-2 and 153-2 to each other. For example, the printed circuit board may have a multilayer printed circuit board structure in which pad patterns of different layers are connected through vias.

Meanwhile, each of the first insulating film 131 and the first metal layer 141 may cover at least a portion of each of the 1-1 and 1-2 pad patterns 151-1 and 151-2. Each of the second insulating film 132 and the second metal layer 143 may cover at least a portion of each of the 2-1 and 2-2 pad patterns 152-1 and 152-2. The first metal layer 141 may cover an upper surface of the 1-1 pad pattern 151-1 so that the upper surface of the 1-1 pad pattern 151-1 is not exposed, and the 2-1 via pattern 162-1 may contact at least a portion of the first metal layer 141. The first metal layer 141 may not cover the exposed upper surface of the 1-2 pad pattern 151-2, and the 2-2 via pattern 162-2 may be spaced apart from the first metal layer 141. The third metal layer 143 may cover an upper surface of the 2-1 pad pattern 152-1 so that the upper surface of the 2-1 pad pattern 152-1 is not exposed, and the 3-1 via pattern 163-1 may contact at least a portion of the third metal layer 143. The third metal layer 143 may not cover the exposed upper surface of the 2-2 pad pattern 152-2, and the 3-2 via pattern 163-2 may be spaced apart from the third metal layer 143.

Meanwhile, each of the 1-1, 1-2, 2-1, 2-2, 3-1, and 3-2 pad patterns 151-1, 151-2, 152-1, 152-2, 153-1, and 153-2 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but an embodiment thereof is not limited thereto. each of the 1-1, 2-1, and 3-1 pad patterns 151-1, 152-1, and 153-1 may include a ground pattern. Each of the 1-2, 2-2, and 3-2 pad patterns 151-2, 152-2, and 153-2 may include a signal pattern. Each of these patterns may have a pad shape. Each of the 1-1, 1-2, 2-1, 2-2, 3-1, and 3-2 pad patterns 151-1, 151-2, 152-1, 152-2, 153-1, and 153-2 may include an electroless plating layer (e.g., chemical copper) and/or an electrolytic plating layer (e.g., electrolytic copper). A sputtering layer may be included instead of an electroless plating layer (or chemical copper), and both thereof may be included if necessary.

Meanwhile, each of the 1, 2-1, 2-2, 3-1, and 3-2 via patterns 161, 161-1, 162-1, 163-1, and 163-2 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but an embodiment thereof is not limited thereto. Each of the 1, 2-1, and 3-1 via patterns 161, 162-1, and 163-1 may include a ground via. Each of the 2-2 and 3-2 via patterns 162-2 and 163-2 may include a signal via.

Each of these vias may have a tapered shape in which a width of an upper portion thereof is wider than a width of a lower portion thereof in cross-section. Each of the 1, 2-1, 2-2, 3-1, and 3-2 via patterns 161, 161-1, 161-2, 163-1, and 163-2 may include an electroless plating layer (e.g., chemical copper) and/or an electrolytic plating layer (e.g., electrolytic copper). A sputtering layer may be included instead of an electroless plating layer (or chemical copper), and both thereof may be included if necessary.

If necessary, the structural features of the printed circuit board 100B according to another example may be applied to a printed circuit board 100E according to another example. Other contents thereof may be substantially the same as described above, and redundant descriptions are omitted.

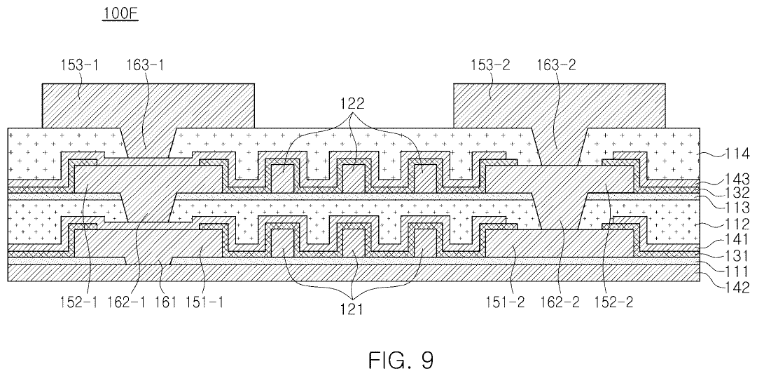

FIG. 9 is a cross-sectional view schematically illustrating another example embodiment of a printed circuit board.

Referring to FIG. 9, in the printed circuit board 100E according to another example described above, a printed circuit board 100F according to another example may further include a third insulating layer 113 disposed between the second insulating layer 112 and the plurality of second wiring patterns 122 and between the second insulating layer 112 and the second insulating film 132. Each of the first and third insulating layers 111 and 113 may include an inorganic insulating material and may be formed to have a thinner thickness. If necessary, the structural features of the printed circuit board 100B according to another example may be applied to a printed circuit board 100F according to another example. Other contents thereof may be substantially the same as described above, and redundant descriptions are omitted.

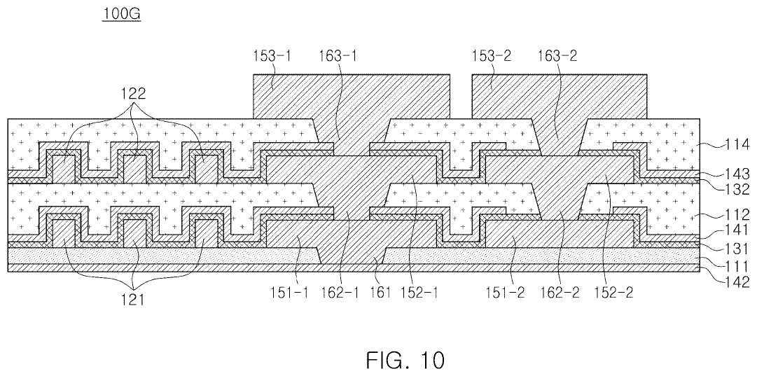

FIG. 10 is a cross-sectional view schematically illustrating another example embodiment of a printed circuit board.

Referring to FIG. 10, in the printed circuit board 100D according to another example described above, a printed circuit board 100G according to an example may further include: 1-1 and 1-2 pad patterns 151-1 and 151-2 respectively disposed on the first insulating layer 111, 2-1 and 2-2 pad patterns 152-1 and 152-2 respectively disposed on the second insulating layer 112, 3-1 and 3-2 pad patterns 153-1 and 153-2 respectively disposed on the fourth insulating layer 114, a first via pattern 161 penetrating through the first insulating layer 111 and connecting the 1-1 pad pattern 151-1 and the second metal layer 142 to each other, a 2-1 via pattern 162-1 penetrating through the second insulating layer 112 and connecting the 1-1 and 2-1 pad patterns 151-1 and 152-1 to each other, a 2-2 via pattern 162-2 penetrating through the second insulating layer 112 and connecting the 1-2 and 2-2 pad patterns 151-2 and 152-2 to each other, a 3-1 via pattern 163-1 penetrating through the fourth insulating layer 114 and connecting the 2-1 and 3-1 pad patterns 152-1 and 153-1 to each other, and a 3-2 via pattern 163-2 penetrating through the fourth insulating layer 114 and connecting the 2-2 and 3-2 pad patterns 152-2 and 153-2 to each other. For example, the printed circuit board may have a multilayer printed circuit board structure in which pad patterns of different layers are connected through vias.

Meanwhile, each of the first insulating film 131 and the first metal layer 141 may cover at least a portion of the 1-1 and 1-2 pad patterns 151-1 and 151-2. Each of the second insulating film 132 and the third metal layer 143 may cover at least a portion of each of the 2-1 and 2-2 pad patterns 152-1 and 152-2. An opening having a relatively narrow width exposing an upper surface of the 1-1 pad pattern 151-1 may be formed in the first insulating film 131 and the first metal layer 141, and the 2-1 via pattern 162-1 may fill this opening, and thus be in contact with at least a portion of each of the first metal layer 141 and the first insulating film 131. An opening having a relatively wide width exposing an upper surface of the 1-2 pad pattern 151-2 may be formed, and the 2-2 via pattern 162-2 may be spaced apart from the first metal layer 141. The 1-2 via pattern 161-2 may be in contact with at least a portion of the first insulating film 131. An opening having a relatively narrow width exposing an upper surface of the 2-1 pad pattern 152-1 may be formed in the second insulating film 132 and the third metal layer 143, and the 3-1 via pattern 163-1 may fill this opening, and thus be in contact with at least a portion of each of the third metal layer 143 and the second insulating film 132. An opening having a relatively wide width exposing an upper surface of the 2-2 pad pattern 152-2 may be formed in the third metal layer 143, and the 3-2 via pattern 163-2 may be spaced apart from the third metal layer 143. The 2-2 via pattern 162-2 may be in contact with at least a portion of the third insulating film 133.

Meanwhile, each of the 1-1, 1-2, 2-1, 2-2, 3-1, and 3-2 pad patterns 151-1, 151-2, 152-1, 152-2, 153-1, and 153-2 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but the present disclosure is not limited thereto. Each of the 1-1, 2-1, and 3-1 pad patterns 151-1, 152-1, and 153-1 may include a ground pattern. Each of the 1-2, 2-2, and 3-2 pad patterns 151-2, 152-2, and 153-2 may include a signal pattern. Each of these patterns may have a pad shape. Each of the 1-1, 1-2, 2-1, 2-2, 3-1, and 3-2 pad patterns 151-1, 151-2, 152-1, 152-2, 153-1, and 153-2 may include an electroless plating layer (e.g., chemical copper) and/or an electrolytic plating layer (e.g., electrolytic copper). A sputtering layer may be included instead of an electroless plating layer (or chemical copper), and both thereof may be included if necessary.

Meanwhile, each of the 1, 2-1, 2-2, 3-1, and 3-2 via patterns 161, 161-1, 161-2, 163-1, and 163-2 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but an embodiment thereof is not limited thereto. Each of the 1, 2-1, and 3-1 via patterns 161, 162-1, and 163-1 may include a ground via. Each of the 2-2 and 3-2 via patterns 162-2 and 163-2 may include a signal via. Each of these vias may have a tapered shape in which a width of an upper portion thereof is wider than a width of a lower portion thereof, in cross-section.

A portion of these vias may be multi-stage vias having stepped side surfaces. Each of the 1, 2-1, 2-2, 3-1, and 3-2 via patterns 161, 161-1, 161-2, 163-1, and 163-3 may include an electroless plating layer (e.g., chemical copper) and/or an electrolytic plating layer (e.g., electrolytic copper). A sputtering layer may be included instead of an electroless plating layer (or chemical copper), and both thereof may be included if necessary.

If necessary, the structural features of the printed circuit board 100B according to another example may be applied to a printed circuit board 100G according to another example. Other contents thereof may be substantially the same as described above, and redundant descriptions are omitted.

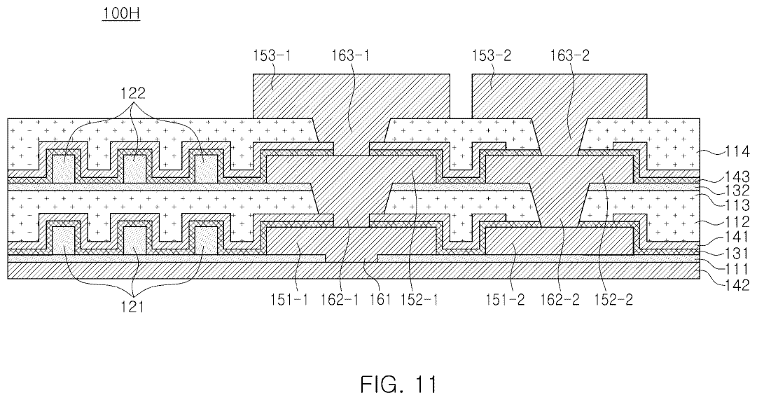

FIG. 11 is a cross-sectional view schematically illustrating another example embodiment of a printed circuit board.

Referring to FIG. 11, in the printed circuit board 100G according to another example described above, a printed circuit board 100H according to another example may further include a third insulating layer 113 disposed between the second insulating layer 112 and the plurality of second wiring patterns 122 and between the second insulating layer 112 and the second insulating film 132. Each of the first and third insulating layers 111 and 113 may include an inorganic insulating material and may be formed to have a thinner thickness. If necessary, the structural features of the printed circuit board 100B according to another example may be applied to a printed circuit board 100H according to another example. Other contents thereof may be substantially the same as described above, and redundant descriptions are omitted.

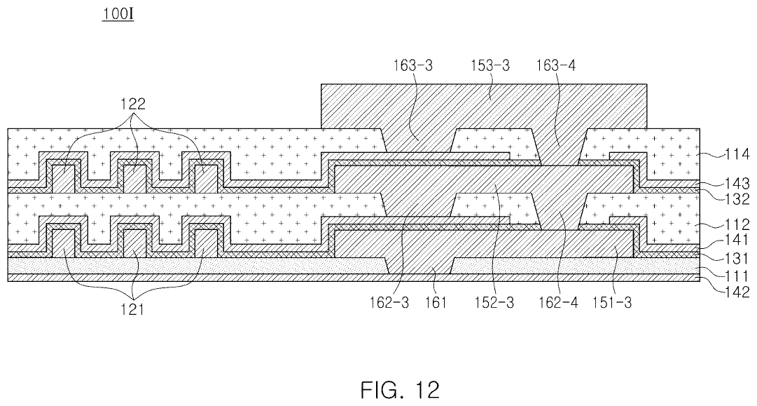

FIG. 12 is a cross-sectional view schematically illustrating another example embodiment of a printed circuit board.

Referring to FIG. 12, in the printed circuit board 100D according to another example described above, a printed circuit board 100I according to another example may further include: a 1-3 pad pattern 151-3 disposed on the first insulating layer 111, a 2-3 pad pattern 152-3 disposed on the second insulating layer 112, a 3-3 pad pattern 153-3 disposed on the fourth insulating layer 114, a first via pattern 161 penetrating through the first insulating layer 111 and connecting the 1-3 pad pattern 151-3 and the second metal layer 142, a 2-3 via pattern 162-3 penetrating through the second insulating layer 112 and connecting the 2-3 pad pattern 152-3 and the first metal layer 141 to each other, a 2-4 via pattern 162-4 penetrating through the second insulating layer 112 and connecting the 1-3 pad pattern 151-3 and the 2-3 pad pattern 152-3 to each other, a 3-3 via pattern 163-3 penetrating through the fourth insulating layer 114 and connecting the 3-3 pad pattern 153-3 and the third metal layer 143 to each other, and a 3-4 via pattern 163-4 penetrating through the fourth insulating layer 114 and connecting the 2-3 pad pattern 152-3 and the 3-3 pad pattern 153-3 to each other. For example, the printed circuit board may have a multilayer printed circuit board structure in which pad patterns of different layers are connected through vias.

Meanwhile, each of the first insulating film 131 and the first metal layer 141 may cover at least a portion of the 1-3 pad pattern 151-3. Each of the second insulating film 132 and the third metal layer 143 may cover at least a portion of the 2-3 pad pattern 152-3. The 2-3 via pattern 162-3 may be in contact with at least a portion of the first metal layer 141 covering the 1-3 pad pattern 151-3. The 2-4 via pattern 162-4 may be spaced apart from the first metal layer 141. The 2-4 via pattern 162-4 may be in contact with at least a portion of the first insulating film 131. The 3-3 via pattern 163-3 may be in contact with at least a portion of the third metal layer 143 covering the 2-3 pad pattern 152-3. The 3-4 via pattern 163-4 may be spaced apart from the third metal layer 143. The 3-4 via pattern 163-4 may be in contact with at least a portion of the second insulating film 132.

Meanwhile, each of the 1-3, 2-3, and 3-3 pad patterns 151-3, 152-3, and 153-3 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but an embodiment thereof is not limited thereto. Each of the 1-3, 2-3, and 3-3 pad patterns 151-3, 152-3, and 153-3 may include a ground pattern. Each of these patterns may have a pad shape. Each of the 1-3, 2-3, and 3-3 pad patterns 151-3, 152-3, and 153-3 may include an electroless plating layer (e.g., chemical copper) and/or an electrolytic plating layer (e.g., electrolytic copper). A sputtering layer may be included instead of an electroless plating layer (or chemical copper), and both thereof may be included if necessary.

Meanwhile, each of the 1, 2-3, 2-4, 3-3, and 3-4 via patterns 161, 161-3, 161-4, 163-3, and 163-4 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but an embodiment thereof is not limited thereto. Each of the 1, 2-3, 2-4, 3-3, and 3-4 via patterns 161, 161-3, 161-4, 163-3, and 163-4 may include a ground via. Each of these vias may have a tapered shape in which a width of an upper portion thereof is wider than a width of a lower portion thereof in cross-section. Each of the 1, 2-3, 2-4, 3-3, and 3-4 via patterns 161, 161-3, 161-4, 163-3, and 163-4: may include an electroless plating layer (e.g., chemical copper) and/or an electrolytic plating layer (e.g., electrolytic copper). A sputtering layer may be included instead of an electroless plating layer (or chemical copper), and both thereof may be included if necessary.

If necessary, the structural features of the printed circuit board 100B according to another example may be applied to a printed circuit board 1001 according to another example. Other contents thereof may be substantially the same as described above, and any duplicate explanations are omitted.

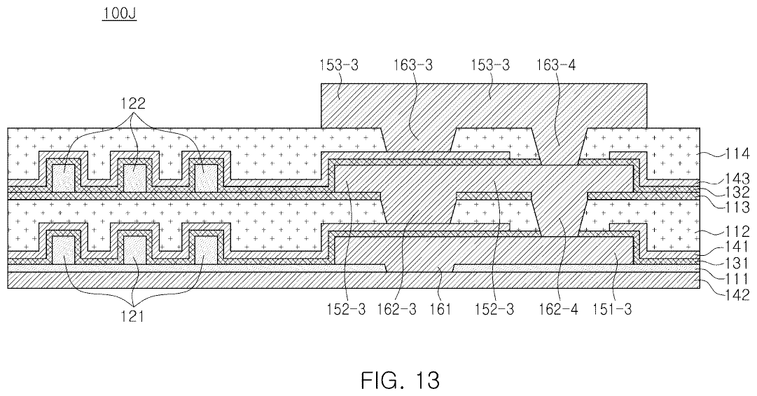

FIG. 13 is a cross-sectional diagram schematically illustrating another example embodiment of a printed circuit board.

Referring to FIG. 13, in the printed circuit board 100I according to another example described above, a printed circuit board 100J according to another example may further include a third insulating layer 113 disposed between the second insulating layer 112 and the plurality of second wiring patterns 122 and between the second insulating layer 112 and the second insulating film 132. Each of the first and third insulating layers 111 and 113 may include an inorganic insulating material, and may be formed to have a thinner thickness. If necessary, the structural features of the printed circuit board 100B according to another example may be applied to the printed circuit board 100J according to another example. Other contents thereof may be substantially the same as described above, and redundant descriptions are omitted.

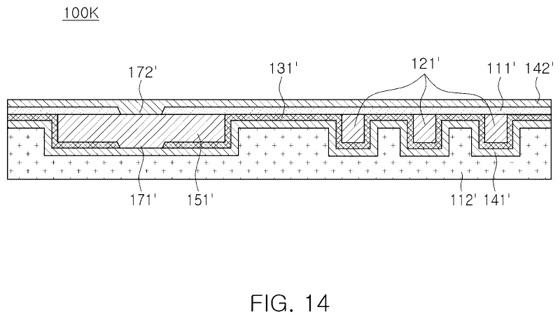

FIG. 14 is a cross-sectional diagram schematically illustrating another example embodiment of a printed circuit board.

Referring to FIG. 14, a printed circuit board 100K according to another example may have a shape which is inverted up and down, in the printed circuit board 100A according to the example described above. For example, the printed circuit board 100K may have an anode pattern structure. For example, a plurality of wiring patterns 121′ may be disposed to be spaced apart from each other on a lower surface of a first insulating layer 111′, respectively. In addition, an insulating film 131′ covering each of the plurality of wiring patterns 121′ may be disposed along a surface of each of the plurality of wiring patterns 121′ on the lower surface of the first insulating layer 111′, and a first metal layer 141′ covering the insulating film 131′ may be arranged along a surface of the insulating film 131′. In addition, a second insulating layer 112′ may be disposed on a lower side of the first metal layer 141′ to cover the first metal layer 141′. In addition, a second metal layer 142′ may be disposed on an upper surface of the first insulating layer 111′. If necessary, a pad pattern 151′ may be further disposed on the lower surface of the first insulating layer 111′, and the insulating film 131′ and the first metal layer 141′ may respectively cover at least a portion of the pad pattern 151′. In addition, each of the insulating film 131′ and the first insulating layer 111′ may have an opening exposing the pad pattern 151′, and each opening may be filled with via patterns 171′ and 172′. Therefore, the first and second metal layers 141′and 142′ may be connected to each other through the pad pattern 151′ and the via patterns 171′ and 172′.

Meanwhile, the contents of each of the first and second insulating layers 111 and 112, the insulating film 131, the plurality of wiring patterns 121, and the first and second metal layers 121 may be substantially equally applied to each of the first and second insulating layers 111′ and 112′, the insulating film 131′, the plurality of wiring patterns 121′, and the first and second metal layers 141′and 142′.

Meanwhile, each of the pad pattern 151′ and the via patterns 171′ and 172′ may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but an embodiment thereof is not limited thereto. The pad pattern 151′ may include a ground pattern, and may have a pad shape. The via patterns 171′ and 172′ may include a ground via, and may have a tapered shape in which a width of an upper portion thereof is wider than a width of a lower portion thereof in cross-section. Each of the pad pattern 151′ and the via patterns 171′ and 172′ may include an electroless plating layer (e.g., chemical copper) and/or an electrolytic plating layer (e.g., electrolytic copper). A sputtering layer may be included instead of an electroless plating layer (or chemical copper), and both thereof may be included if necessary.

If necessary, structural features of the printed circuit board 100B according to another example may be applied to a printed circuit board 100K according to another example. If necessary, the structure of the printed circuit board 100K according to another example may be combined with the structures of each of the printed circuit boards 100C, 100D, 100E, 100F, 100G, 100H, 1001, 100J according to another example. Other contents may be substantially the same as described above, and redundant descriptions are omitted.

In the present disclosure, the term “covering” may include a case of covering at least partially as well as a case of covering completely, and may also include a case of covering not only directly but also indirectly. In addition, the term “filling” may include a case of completely filling but also a case of at least partially filling, and may also include a case of approximately filling. In addition, the term “surrounding” may include a case of surrounding completely as well as a case of surrounding partially, and surrounding approximately. In addition, the term “exposing” may include partially exposing as well as completely exposing, and exposure may refer to exposing from burying the composition.

In this disclosure, determination may be performed by including process errors, positional deviations, errors at the time of measurement, which may occur substantially in a manufacturing process. For example, a substantially constant thickness may include not only a case in which the thickness is completely constant, but also a case in which the thickness is approximately constant. In addition, being substantially coplanar may include not only a case of being present completely on the same plane, but also a case of being present approximately on the same plane.

In the present disclosure, the meaning on a cross-section section may refer to a cross-sectional shape when an object is cut vertically, or a cross-sectional shape when the object is viewed from the side. Furthermore, the meaning on a plane may refer to a planar shape when the object is horizontally cut, or a planar shape when the object is viewed from the top or the bottom.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

As set forth above, as one of the many effects of the present disclosure, a printed circuit board that can reduce signal interference while maintaining a close distance between a plurality of wiring patterns may be provided.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a first insulating layer;
a plurality of first wiring patterns disposed to be spaced apart from each other on the first insulating layer;
a first insulating disposed on the first film insulating layer, and covering each of the plurality of first wiring patterns along a surface of each of the plurality of first wiring patterns;
a first metal layer covering the first insulating film along a surface of the first insulating film; and
a second insulating layer covering the first metal layer, and disposed in at least a portion of spaces between the plurality of first wiring patterns that are spaced apart from each other.

2. The printed circuit board of claim 1, further comprising:
a second metal layer disposed on an opposite side of a side on which the plurality of first wiring patterns of the first insulating layer are disposed,
wherein each of the plurality of first wiring patterns has at least four surfaces substantially surrounded by the first and second metal layers.

3. The printed circuit board of claim 2, wherein each of the plurality of first wiring patterns includes a signal pattern, and
each of the first and second metal layers include a ground pattern.

4. The printed circuit board of claim 1, wherein a thickness of each of the first metal layer and the first insulating film is thinner than a thickness of each of the plurality of first wiring patterns.

5. The printed circuit board of claim 1, wherein each of the first insulating layer and the first insulating film includes an inorganic insulating material, and
the second insulating layer includes an organic insulating material.

6. The printed circuit board of claim 1, wherein each of the plurality of first wiring patterns has a substantially trapezoidal shape in which a width of a surface thereof, adjacent to the first insulating layer is wider than a width of a surface on an opposite side in cross-section.

7. The printed circuit board of claim 1, further comprising:
a plurality of second wiring patterns disposed to be spaced apart from each other on the second insulating layer;
a second insulating film disposed on the second insulating layer, and covering each of the plurality of second wiring patterns along a surface of each of the plurality of second wiring patterns;
a third metal layer covering the second insulating film along a surface of the second insulating film; and
a fourth insulating layer covering the third metal layer, and disposed in at least a portion of spaces between the plurality of second wiring patterns that are spaced apart from each other.

8. The printed circuit board of claim 7, further comprising:
a third insulating layer disposed between the second insulating layer and the plurality of second wiring patterns, and between the second insulating layer and the second insulating film.

9. The printed circuit board of claim 8, wherein each of the first and third insulating layers and the first and second insulating films includes an inorganic insulating material, and
each of the second and fourth insulating layers include an organic insulating material.

10. The printed circuit board of claim 8, further comprising:
a fourth metal layer disposed between the second and third insulating layers,
wherein each of the plurality of second wiring patterns has at least four surfaces substantially surrounded by the third and fourth metal layers.

11. The printed circuit board of claim 8, further comprising:
1-1 and 1-2 pad patterns respectively disposed on the first insulating layer;
2-1 and 2-2 pad patterns respectively disposed on the second insulating layer;
a 2-1 via pattern penetrating through the second insulating layer, and connecting the 1-1 and 2-1 pad patterns to each other; and
a 2-2 via pattern penetrating through the second insulating layer, and connecting the 1-2 and 2-2 pad patterns to each other,
wherein each of the first insulating film and the first metal layer covers at least a portion of each of the 1-1 and 1-2 pad patterns,
each of the second insulating film and the third metal layer covers at least a portion of each of the 2-1 and 2-2 pad patterns,
the 2-1 via pattern is in contact with at least a portion of the first metal layer, and
the 2-2 via pattern is spaced apart from the first metal layer.

12. The printed circuit board of claim 8, further comprising:
a 1-3 pad pattern disposed on the first insulating layer;
a 2-3 pad pattern disposed on the second insulating layer;
a 2-3 via pattern penetrating through the second insulating layer, and connecting the first metal layer and the 2-3 pad pattern to each other; and
a 2-4 via pattern penetrating through the second insulating layer, and connecting the 1-3 and 2-3 pad patterns to each other,
wherein each of the first insulating film and the first metal layer covers at least a portion of the 1-3 pad pattern,
each of the second insulating film and the third metal layer covers at least a portion of the 2-3 pad pattern,
the 2-3 via pattern is in contact with at least a portion of the first metal layer, and
the 2-4 via pattern is spaced apart from the first metal layer.

13. A printed circuit board, comprising:
an insulating layer;
a plurality of wiring patterns disposed to be spaced apart from each other on the insulating layer;
an insulating film disposed on the insulating layer, and covering each of the plurality of wiring patterns conforming to a shape of each of the plurality of wiring patterns; and
a first metal layer covering the insulating film,
wherein the insulating layer and the insulating film include the same type of insulating material.

14. The printed circuit board of claim 13, wherein each of the insulating layer and the insulating film includes an inorganic insulating material.

15. The printed circuit board of claim 13, further comprising:
a second metal layer disposed on an opposite side of a side on which the plurality of wiring patterns of the insulating layer are disposed,
wherein each of the plurality of wiring patterns has at least four surfaces substantially surrounded by the first and second metal layers.

16. A printed circuit board, comprising:
an insulating layer;
a plurality of wiring patterns disposed to be spaced apart from each other on the insulating layer;
an insulating film disposed on the insulating layer, and covering each of the plurality of wiring patterns along a surface of each of the plurality of wiring patterns;
a first metal layer covering the insulating film along a surface of the insulating film; and
a second metal layer disposed on an opposite side of a side on which the plurality of wiring patterns of the insulating layer are disposed,
wherein each of the plurality of wiring patterns has at least four surfaces substantially surrounded by the first and second metal layers, and
a portion of the insulating film disposed between two of the plurality of wiring patterns is in contact with the insulating layer and the first metal layer.

17. The printed circuit board of claim 16, wherein each of the plurality of wiring patterns includes a signal pattern, and
each of the first and second metal layers include a ground pattern.

18. The printed circuit board of claim 16, further comprising:
a pad pattern disposed on the insulating layer; and
a via pattern penetrating through the insulating layer and connecting the pad pattern and the second metal layer each other.

19. The printed circuit board of claim 16, wherein a thickness of each of the first metal layer and the insulating film is thinner than a thickness of each of the plurality of wiring patterns.

20. The printed circuit board of claim 16, wherein each of the insulating layer and the insulating film includes an inorganic insulating material.
